(19) United States
(12) Patent Application Publication
(10) Pub. No.: US 2008/0035981 A1
(43) Pub. Date: Feb. 14, 2008

(54) ONE TIME PROGRAMMABLE MEMORY AND THE MANUFACTURING METHOD THEREOF

(76) Inventors: Ko-Hsing Chang, Hsinchu City (TW); Su-Yuan Chang, Hsinchu Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,444

(22) Filed: Aug. 8, 2006

(51) Int. Cl. H01L 29/788; H01L 21/8238

(52) U.S. Cl. 257/315; 438/211; 257/E29.129

(57) ABSTRACT

A one time programmable memory including a first memory cell is provided. The first memory cell is disposed on a substrate having a trench disposed therein. The first memory cell includes a floating gate, a select gate, a first doped region, a second doped region and a third doped region. The floating gate is disposed on the sidewall of the trench. The select gate is disposed on the substrate outside the trench. The first doped region is disposed in the substrate at the bottom of the trench. The second and third doped regions are disposed in the substrate on both sides of the trench, and the second doped region is disposed between the floating gate and the select gate.

### BACKGROUND OF THE INVENTION

1. Field of the Invention

The present invention relates to a non-volatile memory and a manufacturing method thereof, and more particularly, to a one time programmable memory and a manufacturing method thereof.

2. Description of Related Art

According to the manner of storing data, non-volatile memories can be classified into the following categories: Mask read only memory (ROM), Erasable Programmable ROM (EPROM), Electrically Erasable Programmable ROM (E²PROM), and One Time Programmable ROM (OTPROM).

U.S. Pat. No. 6,678,190 disclosed an OTPROM, wherein two serial-connected P-type transistors on the N-well are used as the select gate and the floating gate respectively. Since no control gate is required, the OTPROM has the advantage of compliance with the Complementary Metal-Oxide Semiconductor (CMOS) process.

However, with the development of the integrated circuit industry, fabricating smaller products with a higher speed becomes the general object in this field. Therefore, the integration of the semiconductor device certainly will be increased continuously. However, the reduced line width often causes the short channel effect, which results in the drop of the threshold voltage (Vt) of the device and poor controlling of the gate voltage (Vg) to the transistor, and besides, the hot electron effect also occurs, as the channel size is reduced, thus adversely influencing the operation of the MOS transistor. All the problems cause misjudgment of the data by the memory, thus reducing the reliability of the memory. Therefore, it can be seen that, how to form a memory with high integration and high reliability has become an urgent problem to be solved.

### SUMMARY OF THE INVENTION

In view of the above, an objective of the present invention is to provide a one time programmable memory, which can reduce the size of the device, increase the integration of the device, while enhancing the reliability of the device.

Another objective of the present invention is to provide a method of manufacturing a highly integrated one time programmable memory.

The present invention provides a one time programmable memory, which includes a first memory cell. The first memory cell is disposed on a substrate having a trench formed therein. The first memory cell includes a floating gate, a select gate, a first doped region, a second doped region and a third doped region. The floating gate is disposed on the sidewall of the trench, the select gate is disposed on the substrate outside the trench, the first doped region is disposed in the substrate at the bottom of the trench, the second and third doped regions are disposed in the substrate on both sides of the select gate, and the second doped region is disposed between the floating gate and the select gate.

In the above one time programmable memory, a second memory cell is disposed adjacent to the first memory cell, and the two adjacent memory cells are disposed in the manner of mirror symmetry.

In the above one time programmable memory, the two adjacent memory cells share the first doped region at the bottom of the trench.

In the above one time programmable memory, the first doped region, the second doped region and the third doped region are P-type doped regions.

In the above one time programmable memory, a floating gate dielectric layer is disposed between the floating gate and the sidewall of the trench. In addition, a select gate dielectric layer is further disposed between the select gate and the substrate.

In the above one time programmable memory, a conductive layer is disposed within the trench and electrically connected to the first doped region.

In the above one time programmable memory, a dielectric layer is disposed between the floating gate and the conductive layer.

In the above one time programmable memory, the material of the dielectric layer includes silicon oxide-Silicon nitride-silicon oxide, and the material of the floating gate and the select gate includes doped polysilicon.

In the above one time programmable memory, the floating gate is disposed within the trench to significantly reduce the size of the memory cell, such that the integration of the device is greatly enhanced. In addition, since the floating gate is disposed on the sidewall of the trench, the channel length can be prolonged, as the depth of the trench increases, thus avoiding the negative influence of the short channel effect.

The present invention provides a manufacturing method of a one time programmable memory, which includes the following steps. First, a substrate with a trench formed therein is provided. Next, a conformal conductive material layer is formed on the substrate, and fills the trench. Next, the conductive material layer is patterned, so as to form a select gate on the substrate outside the trench, and form a floating gate on the sidewall of the trench. Then, doped regions are respectively formed in the substrate at the bottom of the trench, and in the substrate on both sides of the select gate.

In the above manufacturing method of a one time programmable memory, the step of patterning the conductive material layer to form the select gate includes: forming a patterned photoresist layer on the conductive material layer, and forming the select gate on the substrate outside the trench by using the patterned photoresist layer as a mask.

In the above manufacturing method of a one time programmable memory, the step of patterning the conductive material layer to form the floating gate includes: forming a patterned photoresist layer on the conductive material layer, and forming the floating gate on the sidewall of the trench by using the patterned photoresist layer as a mask.

In the above manufacturing method of a one time programmable memory, the material of the conductive material layer includes doped polysilicon.

In the above manufacturing method of a one time programmable memory, the step of forming the doped region includes ion implantation, and the doped region is a P-type doped region.

The above manufacturing method of a one time programmable memory further includes a step of forming a conductive layer in the trench after the step of forming the doped region, wherein the conductive layer is electrically connected to the doped region at the bottom of the trench.

The above manufacturing method of a one time programmable memory further includes a step of forming a dielectric layer in the trench after the step of forming the floating gate and before the step of forming the conductive layer, wherein the dielectric layer covers the floating gate. The material of the dielectric layer includes silicon oxide-silicon nitride-silicon oxide.

The above manufacturing method of a one time programmable memory further includes a step of forming a bottom dielectric layer on the substrate before forming the conductive material layer.

In the above one time programmable memory, the floating gate is formed on the sidewall of the trench, such that the lateral size of the floating gate is reduced, and then the integration of the device is increased. In addition, since the floating gate is disposed on the sidewall of the trench, the channel length can be controlled by controlling the depth of the trench, thus avoiding the short channel effect, and enhancing the reliability of the memory.

In order to make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1D are cross-sectional views of the flow for manufacturing a one time programmable memory according to an embodiment of the present invention.

### DESCRIPTION OF EMBODIMENTS

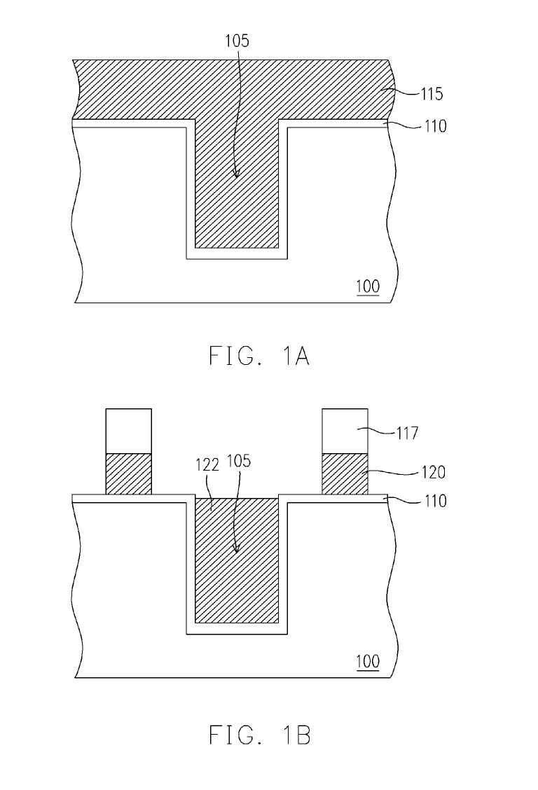

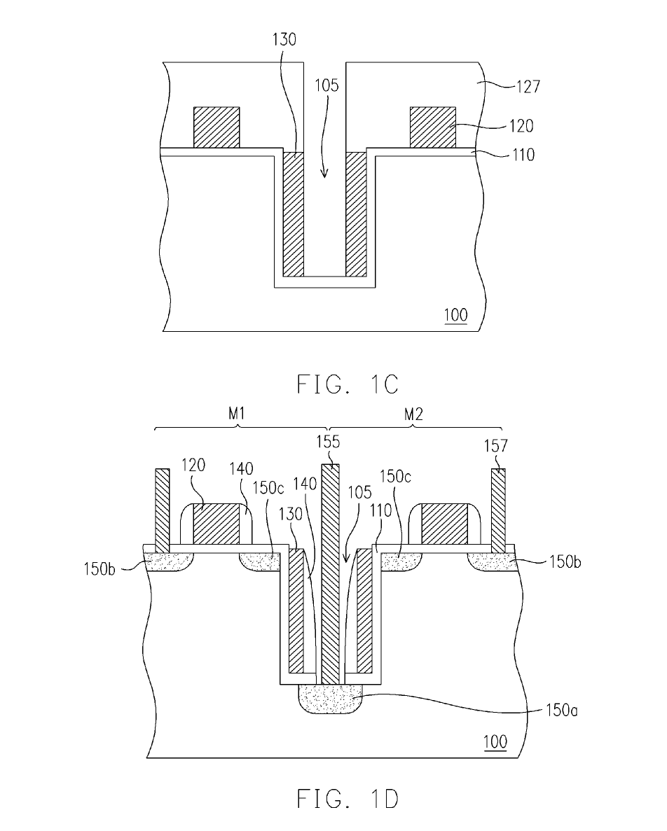

FIG. 1A to FIG. 1D are cross-sectional views of the flow for manufacturing a one time programmable memory according to an embodiment of the present invention.

Referring to FIG. 1A, the method includes, for example, the following steps. A substrate 100, for example, a silicon substrate, having a trench 105 formed there-in is provided. The method of forming the trench 105 includes the following steps. First, a pad (not shown) and a mask layer (not shown) are formed on the substrate 100 and a part of the mask layer is removed by using the photolithography technique. Then, a part of the substrate 100 is removed by using the mask layer as a mask, so as to form the trench 105; and the mask layer and the pad are removed.

Next, a bottom dielectric layer 110 is formed on the substrate 100, the material of the bottom dielectric layer 110 includes, for example, silicon oxide, and is formed by, for example, thermal oxidation or chemical vapor deposition process. The bottom dielectric layer is also formed on the sidewall of the trench 105.

Next, a conformal conductive material layer 115 is formed on the substrate 100, which fills the trench 105 and covers the substrate 100. The material of the conductive material layer 115 is, for example, doped polysilicon, and is formed in the manner of, for example, forming a non-doped polysilicon layer by using the chemical vapor deposition, and performing an ion implantation; or it may be formed by using chemical vapor deposition in situ implantation process.

Referring to FIG. 1B, a patterned photoresist layer 117 is formed on the conductive material layer 115 to cover a part of the conductive material layer 115 on the substrate 100 outside the trench 105, for example. The patterned photoresist layer 117 is formed by, for example, forming a positive photoresist layer on the conductive material layer 115 by spin coating, and developing the pattern after the exposing step.

Next, a part of the exposed conductive material layer 115 is removed by using the patterned photoresist layer 117 as a mask, so as to form the select gate 120 on the substrate 100 outside the trench 105, while maintaining the conductive material layer 122 in the trench 105. A part of the conductive material layer 115 is removed by, for example, wet etching or dry etching.

Referring to FIG. 1C, after forming the select gate 120, the patterned photoresist layer 117 is removed by a wet stripping and dry stripping process. Next, another patterned photoresist layer 127 is formed on the substrate 100, and a part of the conductive material layer 122 in the trench 105 is exposed. The step of forming the patterned photoresist layer 127 may be formed using the process of forming the patterned photoresist layer 117, and therefore this process will not be repeated again hereinafter.

Next, the exposed conductive material layer 122 in the trench 105 is removed by using the patterned photoresist layer 127 as a mask, so as to form the floating gate 130 on the sidewall of the trench 105. The step of removing a part of the conductive material layer 122 is, for example, reactive ion etching process.

Referring to FIG. 1D, after forming the floating gate 130, the patterned photoresist layer 127 is removed by, for example, a dry stripping or a wet stripping process. Next, a dielectric layer 140 is formed on the sidewall of floating gate 130 in the trench 105. The material of the dielectric layer 140 is, for example, silicon oxide, silicon nitride, or a composite dielectric layer formed by silicon oxide-silicon nitride and silicon oxide-silicon nitride-silicon oxide. The dielectric layer 140 is formed by, for example, forming a conformal dielectric material layer (not shown) on the substrate 100, and removing a part of the dielectric material layer with dry etching process, while maintaining the dielectric layer 140 on the sidewall of the floating gate 130. Of course, a dielectric layer 140 may also be formed on the sidewall of the select gate 120, so as to serve as an insulating spacer for the select gate 120.

After forming the dielectric layer 140, a doped region 150a is formed in the substrate 100 at the bottom of the trench 105, and doped regions 150b, 150c are formed in the substrate 100 on both sides of the select gate 120. The doped regions 150a, 150b are, for example, P-type doped regions having dopant of boron, indium and the like, may formed by, for example, ion implantation process.

Next, a conductive layer 155 is formed in the trench 105, which is electrically connected to the doped region 150a in the substrate 100 at the bottom of the trench 105. Of course, a contact window 157 may also be formed on the doped region 150b and may be electrically connected to the doped region 150b. The process of forming the conductive layer 155, the contact window 157, and other subsequent process of completing the fabrication of the one time programmable memory are well-known to those skilled in the art, and therefore will not be described hereinafter.

In the above manufacturing method of a one time programmable memory, a trench 105 is formed in the substrate 100, and the floating gate 130 is formed on the sidewall of the trench 105, so as to reduce the size of the memory device, thus increasing the integration of the memory device. In addition, since the floating gate 130 is disposed on the sidewall of the trench 105, the length of the channel can be controlled by controlling the depth of the trench 105, thereby avoiding the negative influence of the short channel effect, and enhancing the reliability of the memory.

The structure of the one time programmable memory of the present invention is illustrated below. Referring to FIG. 1D, the one time programmable memory includes a plurality of memory cells disposed on the substrate 100. The substrate 100 has a trench 105 formed therein, and each of the memory cells includes a floating gate 130, a select gate 120, a doped region 150a, a doped region 150b and a doped region 150c.

The floating gate 130 is disposed on the sidewall of the trench 105, the select gate 120 is disposed on the substrate 100 outside the trench 105. The material of the floating gate 130 and the select gate 120 is, for example, doped polysilicon. A dielectric layer 140 is disposed on the sidewall of the floating gate 130 and on two sidewalls of the select gate 120. The material of the dielectric layer 140 is, for example, dielectric materials of silicon oxide and silicon nitride, or composite materials formed by multi-layer dielectric materials of silicon oxide-silicon nitride-silicon oxide, for example.

The doped region 150a is disposed in the substrate 100 at the bottom of the trench 105, and the doped regions 150b and 150c are disposed in the substrate 100 on both sides of the select gate 120. The doped region 150a, 150b and 150c are, for example, P-type doped regions having P-type dopant of boron, indium and the like. The adjacent two memory cells M1, M2 have the same structure, and both of them are disposed in the manner of mirror symmetry. In an embodiment, the memory cells M1 and M2, for example, share the doped region 150a at the bottom of the trench 105.

A conductive layer 155 is further disposed in the trench 105, and is electrically connected to the substrate 100 at the bottom of the trench 105, and the material of the conductive layer 155 is, for example, doped polysilicon. A contact window 157 is disposed on the doped region 150b, and the material of the contact window 157 is, for example, the same as that of the conductive layer 155, such as doped polysilicon.

As for the above one time programmable memory, since the floating gate 130 is disposed on the sidewall of the trench 105, the lateral space occupied by the floating gate 130 can be significantly reduced, thereby reducing the size of the memory device and increasing the integration of the memory device. In addition, since the floating gate 130 is disposed in the trench 105, the channel length on the side of the floating gate 130 can be prolonged, thereby alleviating the negative influence of the short channel effect and effectively enhancing the reliability of the memory.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A one time programmable memory, comprising a first memory cell disposed on a substrate having a trench formed therein, the first memory cell comprising:
a floating gate disposed on the sidewall of the trench;
a select gate disposed on the substrate outside the trench;
a first doped region disposed in the substrate at bottom of the trench; and
a second doped region and a third doped region disposed in the substrate on both sides of the select gate respectively, wherein the second doped region is disposed between the floating gate and the select gate.

2. The memory of claim 1, further comprising a second memory cell disposed adjacent to the first memory cell, wherein the two adjacent memory cells are disposed in the manner of mirror symmetry.

3. The memory of claim 2, wherein the two adjacent memory cells share the first doped region at the bottom of the trench.

4. The memory of claim 1, wherein the first doped region, the second doped region and the third doped region are P-type doped regions.

5. The memory of claim 1, further comprising a floating gate dielectric layer disposed between the floating gate and the sidewall of the trench.

6. The memory of claim 1, further comprising a select gate dielectric layer disposed between the select gate and the substrate.

7. The memory of claim 1, further comprising a conductive layer disposed in the trench and electrically connected to the first doped region.

8. The memory of claim 7, further comprising a dielectric layer disposed between the floating gate and the conductive layer.

9. The memory of claim 8, wherein the material of the dielectric layer comprises silicon oxide-silicon nitride-silicon oxide.

10. The memory of claim 1, wherein the material of the floating gate and the select gate comprises doped polysilicon.

11. A manufacturing method of a one time programmable memory, comprising:
providing a substrate having a trench formed therein;
forming a conformal conductive material layer on the substrate, wherein the conductive material layer fills the trench;
patterning the conductive material layer, to form a select gate on the substrate outside the trench, and to form a floating gate on the sidewall of the trench; and
forming a doped region respectively in the substrate at a bottom of the trench, and in the substrate on both sides of the select gate.

12. The method of claim 11, wherein the step of patterning the conductive material layer to form the select gate comprises:
forming a patterned photoresist layer on the conductive material layer; and
forming the select gate on the substrate outside the trench by using the patterned photoresist layer as a mask.

13. The method of claim 11, wherein the method of patterning the conductive material layer to form the floating gate comprises:
forming a patterned photoresist layer on the conductive material layer; and
forming the floating gate on the sidewall of the trench by using the patterned photoresist layer as a mask.

14. The method of claim 11, wherein the material of the conductive material layer comprises doped polysilicon.

15. The method of claim 11, wherein the step of forming the doped region comprises ion implantation.

16. The method of claim 11, wherein the doped region is a P-type doped region.

17. The method of claim 11, further comprising a step of forming a conductive layer in the trench after the step of forming the doped region, wherein the conductive layer is electrically connected to the doped region at the bottom of the trench.

18. The method of claim 17, further comprising a step of forming a dielectric layer in the trench after the step of forming the floating gate and before the step of forming the conductive layer, wherein the dielectric layer covers the floating gate.

19. The method of claim 18, wherein the material of the dielectric layer comprises silicon oxide-silicon nitride-silicon oxide.

20. The method of claim 11, further comprising a step of forming a bottom dielectric layer on the substrate before the step of forming the conductive material layer.
